(19) United States
(12) Patent Application Publication
(10) Pub. No.: US 2023/0185571 A1
(43) Pub. Date: Jun. 15, 2023

(54) INTEGRATED CIRCUIT COMPRISING A HARDWARE CALCULATOR AND CORRESPONDING CALCULATION METHOD

(71) Applicant: ST Microelectronics (Grenoble 2) SAS, Grenoble (FR)

(72) Inventors: Valerie Assemat, Champagnier (FR); Jeremy Ribeiro De Freitas, Coublevie (FR); Edwin Hilkens, Coublevie (FR); Isabelle Carnel, Presles (FR)

(21) Appl. No.: 18/048,757

(22) Filed: Oct. 21, 2022

(30) Foreign Application Priority Data
Oct. 22, 2021 (FR) 2111263

(51) Int. Cl. G06F 9/30

(52) U.S. Cl. CPC G06F 9/3013; G06F 9/3001

(57) ABSTRACT

In an embodiment an integrated circuit includes a hardware calculator configured to calculate in parallel a first output component Yₙ₋₁ of a first rank n−1 and a second output component Yₙ of a second rank n which is higher than and consecutive to the first rank, according to the formula: Yₘ=Σₖ₌₀^{N-1}bₖxₘ₋ₖ, in a series of operations, wherein the hardware calculator includes a first calculation path dedicated to the first output component Yₙ₋₁, a second calculation path dedicated to the second output component Yₙ, wherein, for each operation, a first register is configured to contain a pair of first factors {xᵢ, xᵢ₋₁} corresponding to terms {bₖxₘ₋ₖ}_{[k;k+1]}^{m=n-1} of an operation in the first path, a second register is configured to contain a pair of second factors {bⱼ, bⱼ₊₁} corresponding to terms {bₖxₘ₋ₖ}_{[k;k+1]}^{m=n-1} of the operation in the first path, and a third register is configured to contain a pair of second factors {bⱼ₊₂, bⱼ₊₃} corresponding to terms {bₖxₘ₋ₖ}_{[k+2;k+3]}^{m=n-1} of the next operation in the first path.

### CROSS-REFERENCE TO RELATED APPLICATIONS

This application claims the benefit of French Application No. 2111263, filed on Oct. 22, 2021, which application is hereby incorporated herein by reference.

### TECHNICAL FIELD

Embodiments and implementations relate to the hardware calculators, carried out in an integrated manner, in particular adapted to perform parallel calculations of the output vector components of a convolution product.

### BACKGROUND

Typically, and in particular in finite impulse response “FIR” filter algorithms, a convolution product between an input vector {xᵢ}_{0≤i≤M-1} and another input vector {bᵢ}_{0≤i≤N-1} results in an output vector {Yₘ}_{0≤m≤N-1} whose each component is defined by the formula Yₘ=Σₖ₌₀^{N-1}bₖxₘ₋ₖ.

Usually, the data of the input vector {xᵢ}_{0≤i≤M-1} can be called “samples” and the data of the input vector {bᵢ}_{0≤i≤N-1} can be called “taps”.

### SUMMARY

Hardware calculators can be specifically dedicated to the calculations of the multiplication and accumulation type “MAC” of the components Yₘ of the output vector of such a convolution product. The use of hardware calculators allows optimising the workload of a general-purpose calculation unit, typically a processor of a system-on-chip, and to optimise the calculation time of the output vector, called inference time.

Optimised hardware calculators are capable, in one instruction, of simultaneously performing two multiplication-accumulation calculations, as well as a loading of the next two samples xᵢ and a loading of the next two taps bᵢ for the next two multiplication-accumulation operations.

Thus, the number of multiplications-accumulations to calculate all components of the output vector is equal to the product of the number of samples xᵢ by the number of taps bᵢ, for example N×M according to the example of dimensions given above. And, the number of sample and taps loadings is also equal to N×M.

The applications of convolution products executed by hardware calculators tend to increase the dimension N, which has a quadratic impact on the inference time of said calculations.

Multiplying the number of MAC type calculators in parallel allows optimising the number of successive instructions, but requires multiplying the number of input data loading processes at each instruction. Loading samples and taps, from memories, can become the time limiting factor to calculate the convolution product.

Embodiments provide optimization of multiplication-accumulation techniques in order to reduce the time required for the complete computation of the convolution product.

Various embodiments provide performing, for each operation, four multiplications-accumulations with only two loadings of input data.

According to one embodiment, there is proposed in this regard an integrated circuit comprising a hardware calculator adapted to calculate in parallel a first output component Yₙ₋₁ of a first rank n−1 and a second output component Yₙ of a second rank n which is higher than and consecutive to the first rank, according to the formula: Yₘ=Σₖ₌₀^{N-1}bₖxₘ₋ₖ, in a series of operations, the hardware calculator including a first calculation path dedicated to the first output component Yₙ₋₁, a second calculation path dedicated to the second output component Yₙ, in which, for each operation, a first register is configured to contain a pair of first factors {xᵢ, xᵢ₋₁} corresponding to the terms {bₖxₘ₋ₖ}_{[k;k+1]}^{m=n-1} of said operation in the first path, a second register is configured to contain a pair of second factors {bⱼ, bⱼ₊₁} corresponding to the terms {bₖxₘ₋ₖ}_{[k;k+1]}^{m=n-1} of said operation in the first path, and a third register is configured to contain a pair of second factors {bⱼ₊₂, bⱼ₊₃} corresponding to the terms {bₖxₘ₋ₖ}_{[k+2;k+3]}^{m=n-1} of the next operation in the first path, the two calculation paths being configured to each access the first register, the second register and the third register, so as to use, in each operation, the first factors xₘ₋ₖ and the second factors bₖ at the corresponding position of the summation index 0≤k≤N−1 in said formula of rank m=n−1, m=n respective to each of the output components Yₙ₋₁, Yₙ.

Thus, for each operation, the first calculation path uses factors provided for this operation contained in the first register and in the second register, while the second calculation path uses the factors corresponding to the second rank m=n et and to the corresponding position of the summation index 0≤k≤N−1 common with the second factors of said operation in progress in the first path and with the next operation in the first path.

According to one embodiment, for each operation:

the first calculation path is configured to calculate and accumulate, in a first output register, the pair of two products {bₖxₘ₋ₖ}_{[k;k+1]}^{m=n-1} between the first factors {xᵢ, xᵢ₋₁} contained in the first register and the second factors {bⱼ, bⱼ₊₁} contained in the second register,
the second calculation path is configured to calculate and accumulate, in a second output register, the pair of two products {bₖxₘ₋ₖ}_{[k;k+1]}^{m=n} between the same first factors {xᵢ, xᵢ₋₁} contained in the first register and the second factors {bⱼ₊₁, bⱼ₊₂} corresponding to the calculation of the second rank n, contained in the second register and in the third register;
the hardware calculator is configured to load, into the first register, a pair of first factors {xᵢ₋₂, xᵢ₋₃} corresponding to the calculation of the next operation of the first path, and to load, into the second register, a pair of second factors {bⱼ₊₄, bⱼ₊₅} corresponding to the calculation of the operation following the next operation of the first path.

Indeed, the configuration of the two calculation paths accessing the three input registers, allows performing only two loadings to be carried out for each operation to allow the four multiplication-accumulation of the following operation.

According to another embodiment, an integrated circuit is proposed comprising a hardware calculator adapted to calculate in parallel a first output component Yₙ₋₁ of a first rank n−1 and a second output component Yₙ of a second rank n which is higher than and consecutive to the first rank, according to the formula: Yₘ=Σₖ₌₀^{N-1}bₖxₘ₋ₖ, in a series of operations the hardware calculator including a first calculation path dedicated to the first output component Yₙ₋₁, a second calculation path dedicated to the second output component Yₙ, a first register intended to contain a pair of first factors {xᵢ, xᵢ₋₁}, a second register intended to contain a pair of second factors {bⱼ, bⱼ₊₁} and a third register intended to contain a pair of second factors {bⱼ₊₂, bⱼ₊₃}, wherein, for each operation, the hardware calculator is configured to:

with the first path, calculate and accumulate, in a first output register, a pair of two products {bₖxₘ₋ₖ}_{[k;k+1]}^{m=n-1} between the first factors {xᵢ, xᵢ₋₁} contained in the first register and the second factors {bⱼ, bⱼ₊₁} contained in the second register;
with the second path, calculate and accumulate, in a second output register, a pair of two products {bₖxₘ₋ₖ}_{[k;k+1]}^{m=n} between the same first factors {xᵢ, xᵢ₋₁} contained in the first register and the second factors {bⱼ₊₁, bⱼ₊₂} corresponding to the calculation of the second rank n, contained in the second register and in the third register;
load, into the first register, a pair of first factors {xᵢ₋₂, xᵢ₋₃} corresponding to the calculation of the next operation of the first path,
load, into the second register, a pair of second factors {bⱼ₊₄, bⱼ₊₅} corresponding to the calculation of the operation following the next operation of the first path.

In other words, the two calculation paths are configured to each access the first register, the second register and the third register, so as to use in each operation the first factors xₘ₋ₖ and the second factors bₖ common for the ranks m=n−1; m=n of each of the output components Yₙ₋₁, Yₙ, and at the corresponding position of the summation index 0≤k≤N−1 in said respective formula at the rank of each of the output components Yₙ₋₁, Yₙ.

As a consequence of this configuration of the two multiplication-accumulation calculation paths being able to access the three registers, the hardware calculator is capable of calculating four multiplication-accumulation terms for two loadings of factors in said registers, for each operation.

Indeed, the loading of the second factors {bⱼ₊₄, bⱼ₊₅} corresponding to the calculation of the operation following the next operation of the first path; allows, during the next operation:

having available the second factors {bⱼ₊₄, bⱼ₊₅} (loaded into the register called “second register” during the previous operation) which will be used in the following operation by the first path, but which are used, at least partially (at least one), in this operation by the second path; and
having available the second factors {bⱼ₊₂, bⱼ₊₃} (loaded into the register called “third register” during the operation prior to the previous operation), used in this operation by the first path and used, at least partially (at least one), in this operation by the second path.

In fact, the qualifications “second” and “third” registers are arbitrary, that is to say that the integrated circuit materially comprises these two registers which can alternately have the function defined above of the second register and the function defined above of the third register. For example if, during an operation, (resp.) one of the registers fulfils the function of the “second” register then (resp.) the other fulfils the function of the “third” register, while during another operation (next operation), said (resp.) one will fulfil the function of the “third” register and (resp.) the other will fulfil the function of the “second” register.

For example, in this regard, the hardware calculator is configured, in the series of operations, to switch the functions of the second register and of the third register, for each successive operation.

According to one embodiment, the first register, the second register, the third register as well as the first output register and the second output register have a size of 2M bits, for example 64 bits (M=32), and each contain a pair of two data encoded on M bits, for example 32 bits (M=32).

According to one embodiment, the hardware calculator includes a selection circuit configured to distribute the accesses to the second register and to the third register at the first calculation path and the second calculation path, such that the first path has access to the second factors {bⱼ, bⱼ₊₁} corresponding to said operation contained in the second register, and that the second path has access to the second factors {bⱼ₊₂, bⱼ₊₃} corresponding to said operation contained in the second register and in the third register.

In other words, unlike conventional hardware calculators, the input registers are not dedicated to a single calculation path, but are mutualised and distributed between the different calculation paths via the selection circuit.

According to one embodiment, the hardware calculator is further adapted to calculate in parallel a third output component Yₙ₊₁, of a third rank n+1 which is higher than and consecutive to the second rank n, according to the same formula, the hardware calculator including a third calculation path dedicated to the third output component Yₙ₊₁,

and in which, for each operation, the hardware calculator is further configured to:
with the third path, calculate and accumulate in a third output register a pair of two products {bₖxₘ₋ₖ}_{[k;k+1]}^{m=n+1} between the same first factors {xᵢ, xᵢ₋₁} contained in the first register and the second factors {bⱼ₊₂, bⱼ₊₃} corresponding to the calculation of the third rank n+1, contained in the third register.

Thus, with a third calculation path configured for itself also to access the first register, the second register and the third register, it is possible to use for each operation the first factors xₘ₋ₖ and the second factors bₖ, further common for the rank m=n+1 and at the corresponding position of the summation index 0≤k≤N−1 in said formula.

As a consequence of this configuration of the three multiplication-accumulation calculation paths being able to access the three registers, the hardware calculator is capable of calculating six multiplication-accumulation terms for two loadings of factors into said registers, for each operation.

Indeed, the loading of the second factors {bⱼ₊₄, bⱼ₊₅} corresponding to the calculation of the operation following the next operation of the first path; further allows, during the next operation: having available the second factors {bⱼ₊₄, bⱼ₊₅} (loaded in the register called “second register” during the previous operation) which will be used in the next operation by the first path, but which are used, at least partially, in this operation by the second path, and which are further used in this operation through the third path.

According to one embodiment, the integrated circuit defined above incorporates a digital signal processor.

According to another aspect, there is proposed a method, implemented within a hardware calculator, of parallel calculation of a first output component Yₙ₋₁ of a first rank n−1 and of a second output component Yₙ of a second rank n which is higher than and consecutive to the first rank, according to the formula: Yₘ=Σₖ₌₀^{N-1}bₖxₘ₋ₖ, in a series of operations, in which, for each operation:

the calculation of the first component Yₙ₋₁ comprises a calculation and an accumulation of two products {bₖxₘ₋ₖ}_{[k;k+1]}^{m=n-1} between first factors {xᵢ, xᵢ₋₁} contained in a first register and second factors {bⱼ, bⱼ₊₁} contained in a second register;
the calculation of the second component Yₙ comprises a calculation and an accumulation of two products {bₖxₘ₋ₖ}_{[k;k+1]}^{m=n} between the same first factors {x₁, xᵢ₋₁} contained in the first register and the second factors {bⱼ₊₁, bⱼ₊₂} corresponding to the calculation of the second rank n, contained in the second register and in a third register;
a loading, into the first register, of a pair of first factors {xᵢ₋₂, xᵢ₋₃} corresponding to the calculation of the next operation,
a loading, into the second register, of a pair of second factors {bⱼ₊₄, bⱼ₊₅} corresponding to the calculation of the operation following the next operation of the first path.

According to one embodiment, the method comprises, in the series of operations, a switching of the functions of the second register and of the third register, for each successive operation.

According to one embodiment, the first register, the second register, the third register as well as the first output register and the second output register have a size of 2M bits and each contain a pair of two data items encoded on M bits.

According to one embodiment, the accesses to the second register and to the third register are distributed such that a first calculation path dedicated to the first output component Yₙ₋₁, has access to the second factors {bⱼ, bⱼ₊₁} corresponding to said operation contained in the second register, and that a second calculation path dedicated to the second output component Yₙ, have access to the second factors {bⱼ₊₂, bⱼ₊₃} corresponding to said operation contained in the second register and in the third register.

According to one embodiment, the method further comprises a parallel calculation of a third output component Yₙ₊₁, of a third rank n+1 which is higher than and consecutive to the second rank n, according to the same formula, in which, for each operation:

the calculation of the third component Yₙ₊₁ comprises a calculation and an accumulation of two products {bₖxₘ₋ₖ}_{[k;k+1]}^{m=n+1} between the same first factors {xᵢ, xᵢ₋₁} contained in the first register and the second factors {bⱼ₊₂, bⱼ₊₃} corresponding to the calculation of the third rank n+1, contained in the third register.

### BRIEF DESCRIPTION OF THE DRAWINGS

Other advantages and features of the invention will become apparent on examining the detailed description of embodiments and implementations, with no limitation, and of the appended drawings, in which:

FIG. 1 illustrates a hardware calculator according to embodiments;

FIG. 2 illustrates an implementation principle according to embodiments;

FIG. 3 illustrates a hardware calculator with respect to a first operation according to embodiments;

FIG. 4 illustrates an implementation principle of a second operation according to embodiments;

FIG. 5 illustrates a hardware calculator with respect to a second operation after the first operation according to embodiments;

FIG. 6 illustrates a further implementation principle according to embodiments; and

FIG. 7 illustrates an exemplary embodiment of the hardware calculator.

### DETAILED DESCRIPTION OF ILLUSTRATIVE EMBODIMENTS

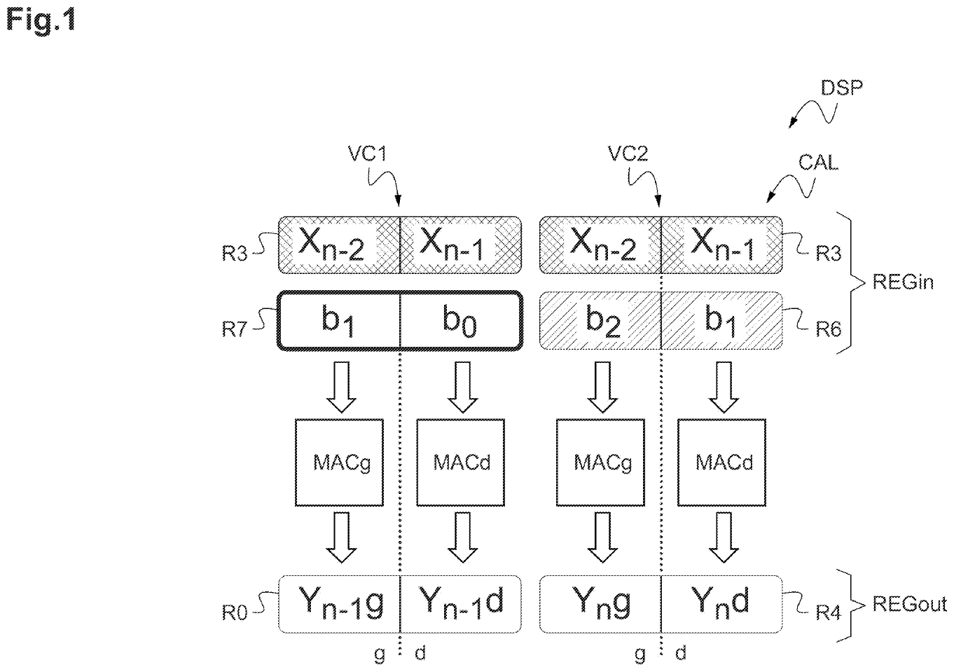

FIG. 1 illustrates an example of a hardware calculator CAL in particular adapted to calculate convolution products. The hardware calculator can be produced within an integrated circuit of a digital signal processor DSP.

The components of an output vector of a convolution product can be expressed by the general formula Yₘ=Σₖ₌₀^{N-1}bₖxₘ₋ₖ, which is a sum where each term is the product of factors. The factors are input data for the convolution. The first factors xₘ₋ₖ are for example components of an input vector, otherwise called “samples”, the second factors bₖ are for example coefficients, otherwise called “taps”.

The hardware calculator CAL comprises two parallel calculation paths VC1, VC2, each configured to perform multiplication-accumulation operations MACg, MACd, in a series of successive operations, such that the terms accumulated in the output registers REGout compose progressively an output component Yₘ at the end of the series. Each operation comprises a multiplication of the data xₘ₋ₖ, bₖ contained in respective input registers REGin, and an accumulation of the products in an output register REGout. Furthermore, in an operation, a loading of the input data of a next operation can be done in the input registers REGin.

The calculation paths VC1, VC2 advantageously include a first optimisation of the use of the input REGin and output REGout registers, allowing limiting the number of loading of the input data in the series of operations. Indeed, the registers REGin and REGout have a size of 2M bits, for example 64 bits (M=32) and each contain two distinct data encoded on M bits, for example 32 bits. Arbitrarily, in each 64-bit register, a distinction is thus made between the 32-bit word stored on the left in the drawings by the reference “g”, and the 32-bit word stored on the right in the drawings by the reference “d”.

Thus, in each calculation path VC1, VC2, a single loading of a word of 2M bits into an input register REGin allows loading both a first input factor for a first multiplication-accumulation MACg performed in the left portion “g” of the input-output registers REGin, REGout, and another first input factor for a second multiplication-accumulation MACd performed in parallel in the right portion “d” of the input-output registers REGin, REGout. For example, the calculations in the left “g” and right “d” portions of the registers REGin, REGout can be implemented, such that the terms of the sum Σₖ₌₀^{N-1}bₖxₘ₋ₖ having an even index k are accumulated in the right portion “d” of the output register REGout, while the terms having an odd index k are accumulated in the left portion “g” of the output register REGout.

Thus, independently in each of the paths VC1, VC2 and at each operation, two 64-bit loadings are sufficient to carry out two multiplications-accumulations MACg, MACd.

Furthermore, the two calculation paths VC1, VC2 can advantageously share one of the two input registers REGin, for example the input register R3 storing input data xₙ₋₁, xₙ₋₂, and perform the multiplication-accumulation operations with the coefficients bₖ having the indices k corresponding to these input data in the sum Σₖ₌₀^{N-1}bₖxₘ₋ₖ relative to the rank m of the output component Yₘ=Σₖ₌₀^{N-1}bₖxₘ₋ₖ, respective to each calculation path VC1, VC2.

For example, the first path VC1 calculates the output component Yₙ₋₁ of a first rank n−1 and the second path calculates the second output component Yₙ of a second rank n. Then, in the first path VC1 at the rank m=n−1, the coefficients bₖ are loaded, having the indices k, k+1 corresponding to the products {bₖxₘ₋ₖ}ₖ^{m=n-1} for the input data xₙ₋₁, xₙ₋₂, (i.e. (n−1)−k=n−1; (n−1)−(k+1)=n−2 i.e. k=0, (k+1)=1), that is to say the coefficients b₀ and b₁, in the second input register R7. Similarly, in the second path VC2 at rank m=n, the coefficients bₖ are loaded, having the indices k, k+1 corresponding to the products {bₖxₘ₋ₖ}ₖ^{m=n} for the input data xₙ₋₁, xₙ₋₂, (i.e. n−k=n−1; n−(k+1)=n−2 i.e. k=1, (k+1)=2), that is to say the coefficients b₁ and b₂, in the third input register R6.

This allows mutualising, in the set of the two paths VC1, VC2 and for each operation, a 64-bit loading in the common register R3, such that three 64-bit loadings are sufficient to carry out four multiplications-accumulations for each operation in the set of the two paths VC1, VC2.

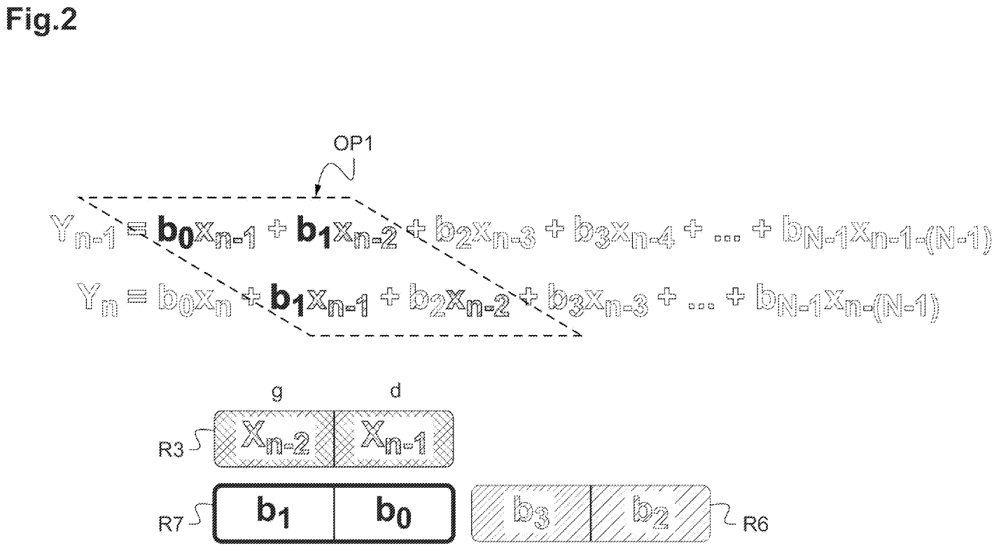

Reference is now made to FIGS. 2 to 5 illustrating an advantageous example allowing reducing to two the number of loadings in the input registers REGin (FIG. 1) in order to carry out the four multiplications-accumulations at each operation in the set of the two paths VC1, VC2.

FIG. 2 illustrates the implementation principle allowing mutualising an additional loading in the input registers R3, R7, R6, for the first calculation path VC1 and the second calculation path VC2 as described above in relation with FIG. 1.

On the one hand, the first rank n−1 of the first output component Yₙ₋₁ calculated by the first path VC1, and the second rank n of the second output component Yₙ calculated by the second path VC2, are advantageously consecutive with each other. The case where the second rank n is higher than and directly consecutive to the first rank n−1. This corresponds to the case described in relation to FIG. 1.

In FIGS. 2, 4 and 6, the representation of the equations Yₙ₋₁, Yₙ are the expansion of the formula Yₘ=Σₖ₌₀^{N-1}bₖxₘ₋ₖ for the respective ranks n−1, n in which the letter filling patterns correspond to the pattern of the input register R3, R7, R6 which contains the respective factors, the “empty” or “white” pattern meaning that these factors are not loaded into a register during the operation OP1.

During a first operation OPi, performed with the input data xₙ₋₁, xₙ₋₂, the coefficients b₀ and b₁ used by the first VC1 are contained in the second register R7. For the same input data xₙ₋₁, xₙ₋₂, the coefficient b₁ used by the second path VC2 is contained in the second register R7, the coefficient b₂ used by the second path VC2 is contained in the third register R6.

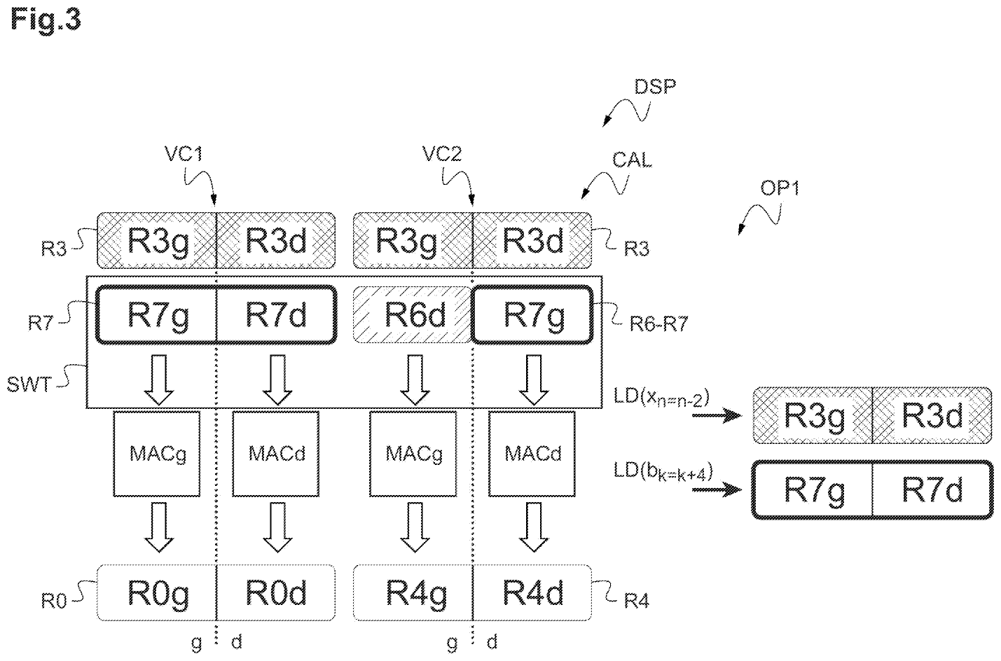

Reference is made to FIG. 3, illustrating the hardware calculator CAL in the context of the implementation of the first operation OP1.

In the first path VC1, the multiplication-accumulation operation is implemented as described in relation to FIG. 1, that is to say that the two products {bₖxₘ₋ₖ}_{[k;k+1]}^{m=n-1} between the first factors {xₙ₋₁, xₙ₋₂} contained in the first register R3 and the second factors {b₀, b₁} contained in the second register R7 are accumulated in the output register Ro of the first path VC1.

In details, the product between the first factor xₙ₋₁ and the second factor b₀ is accumulated in the right portion of the output register Rod, from the data contained in the right portion of the first register R3d and in the right portion of the second register R7d. This multiplication-accumulation operation “Rod+=R3d*R7d” (“+=” meaning “accumulation”, “*” meaning “multiplication”). Likewise, the product of the other first factor xₙ₋₂ and the other second factor b₁ is accumulated in the left portion of the output register Rog, such as “Rog+=R3g*R7g”.

In the second path VC2, the multiplication-accumulation operation is implemented such that the two products {bₖxₘ₋ₖ}_{[k;k+1]}^{m=n} between the first factors {xₙ₋₁, xₙ₋₂} contained in the first register R3 and the second factors {b₁, b₂} contained in the second register R7 and in the third register R6 are accumulated in the output register R4 of the second path VC2.

In details, in the second path VC2, the product between the first factor xₙ₋₁ and the second factor b₁ is accumulated in the right portion of the output register R4d, from the data contained in the right portion of the first register R3d and in the left portion of the second register R7d, such as “R4d+=R3d*R7g”. And, the product between the other first factor xₙ₋₂ and the other second factor b₂ is accumulated in the left portion of the output register R4g, from the data contained in the left portion of the first register R3g and in the right portion of the third register R6d, such as “R4g+=R3g*R7d”.

In this regard, the hardware calculator CAL may include a selection circuit SWT configured to distribute the accesses to the second register R7 and to the third register R6, at the first calculation path VC1 and at the second calculation path VC2. The selection circuit SWT is configured to distinctly distribute the left and right portions of said registers R7, R6.

In the first operation OP1, the distribution is made such that the left portion MACg of the first path VC1 receives as input the left portion of the first register R3g and the left portion of the second register R7g; the right portion MACd of the first path VC1 receives as input the right portion of the first register R3d and the right portion of the second register R7d. While the left portion MACg of the second path VC2 receives as input the left portion of the first register R3g and the right portion of the third register R6d; and the right portion MACd of the second path VC2 receives as input the right portion of the first register R3d and the left portion of the second register R7g.

Thus the first path VCi has access to the second factors {bⱼ, bⱼ₊₁} of the corresponding operation contained in the second register R7, and the second path VC2 has access to the second factors {bⱼ₊₂, bⱼ₊₃} of the corresponding operation contained in the second register R7g and in the third register R6d.

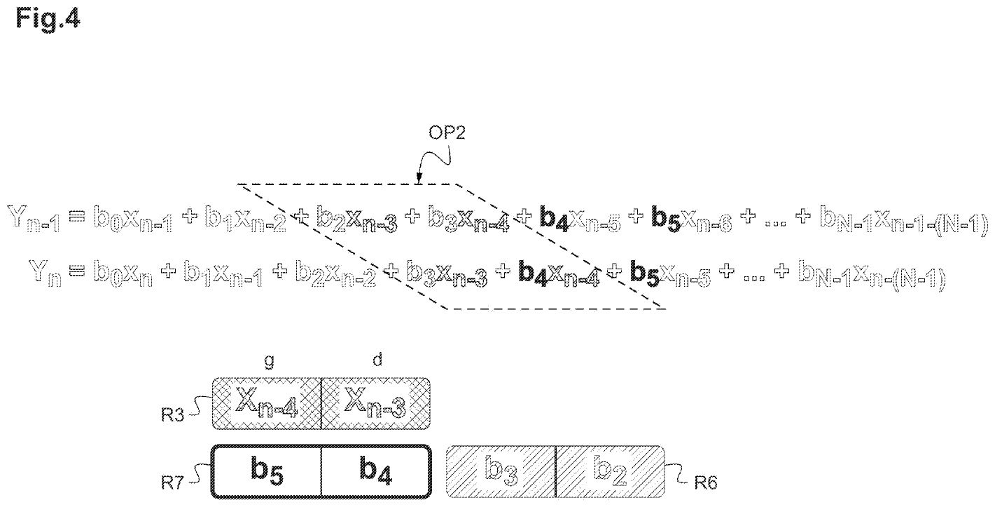

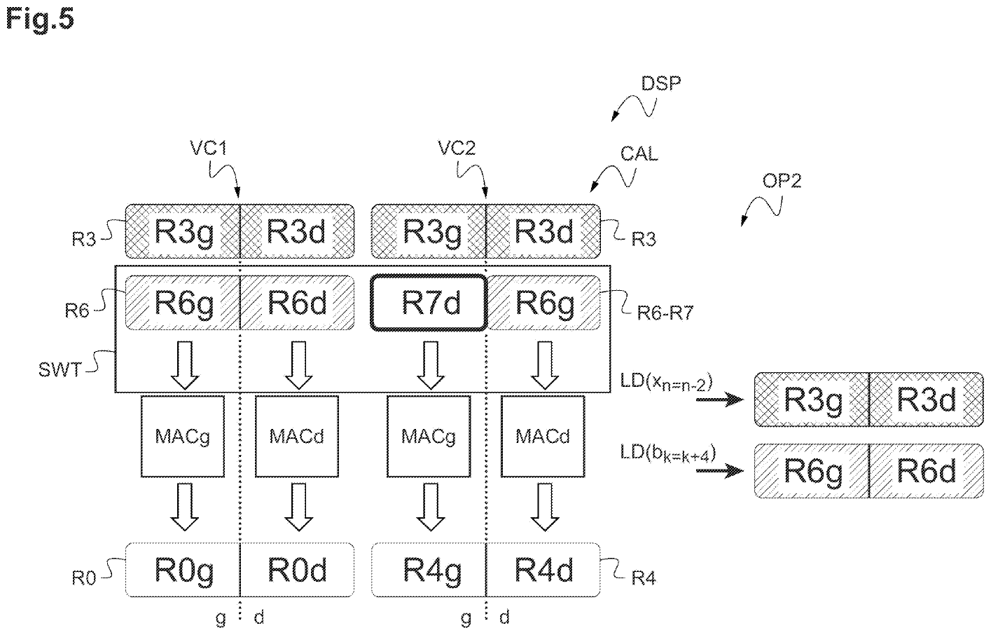

Simultaneously with the parallel multiplication-accumulation calculations in the two calculation paths VC1, VC2, the hardware calculator CAL is configured to perform, in the first register R3, a loading LD(xₙ₌ₙ₋₂) of the pair of first factors {xₙ₋₃, xₙ₋₄} corresponding to the calculation of the next operation OP2 (FIGS. 4 and 5) of the first path VC1 and of the second path VC2; as well as, in the second register R7, only one other loading LD(bₖ₌ₖ₊₄) of the pair of second factors {b₄, b₅} corresponding to the calculation of the operation following the next operation OP2 of the first path VC1.

Consequently, during the next operation OP2, the second register R7 and the third register R6 will contain second factors {b₂, b₃} {b₄, b₅} in a manner comparable to their content at the beginning of the first operation OP1.

Reference is made in this regard to FIG. 4.

FIG. 4 illustrates the principle of implementation of the calculations in the first path VC1 and in the second path VC2, during the next operation after the first operation OP1, that is to say during the second operation OP2.

It is recalled that at the end of the loadings performed during the first operation OP1, the first input register R3 contains the input data xₙ₋₃, xₙ₋₄, the second input register R7 contains the coefficients b₄ and b₅ corresponding to the products {bₖxₘ₋ₖ}ₖ^{m=n-1} for the input data xₙ₋₅, xₙ₋₆ of the operation following the second operation OP2, in the first path VC1. The third register R6 has not been loaded with new data, and therefore contains the coefficients b₂ and b₃, corresponding to the products {bₖxₘ₋ₖ}ₖ^{m=n-1} for the input data xₙ₋₃, xₙ₋₄ of the operation following the first operation OP1, in the first path VC1, that is to say the second operation OP2 in progress in the first path VC1.

During the second operation OP2, with the input data xₙ₋₃, xₙ₋₄, the coefficients b₂ and b₃ or the first VC1 are contained in the third register R6. For the same input data xₙ₋₃, xₙ₋₄, the coefficient b₃ used by the second path VC2 is contained in the third register R6, and the coefficient b₄ used by the second path VC2 is contained in the second register R7.

Reference is made to FIG. 5, illustrating the hardware calculator CAL in the context of the implementation of the second operation OP2, following (after) the first operation OP1.

In the first path VC1, the multiplication-accumulation operation is implemented such that the two products {bₖxₘ₋ₖ}_{[k;k+1]}^{m=n-1} between the first factors {ₙ₋₃, xₙ₋₄} contained in the first register R3 and the second factors {b₂, b₃} contained in the third register R6 are accumulated in the output register Ro of the first path VC1.

In detail, the multiplication-accumulation in the right portion of the output register Rod of the first path VC1 is expressed “Rod+=R3d*R6d”, and the multiplication-accumulation in the left portion of the output register Rog is expressed “Rog+=R3g*R6g”.

In the second path VC2, the multiplication-accumulation operation is implemented such that the two products {bₖxₘ₋ₖ}_{[k;k+1]}^{m=n} between the first factors {xₙ₋₃, xₙ₋₄} contained in the first register R3 and the second factors {b₃, b₄} contained in the second register R7 and in the third register R6 are accumulated in the output register R4 of the second path VC2.

In detail, the multiplication-accumulation in the right portion of the output register R4d of the second path VC2 is expressed “R4d+=R3d*R6g”, and the multiplication-accumulation in the left portion of the output register R4g is expressed “R4g+=R3g*R7d”.

Herein again, the selection circuit SWT is configured to make the distribution such that the left portion MACg of the first path VC1 receives as input the left portion of the first register R3g and the left portion of the third register R6g; the right portion MACd of the first path VC1 receives as input the right portion of the first register R3d and the right portion of the third register R6d. While the left portion MACg of the second path VC2 receives as input the left portion of the first register R3g and the right portion of the second register R7d; and the right portion MACd of the second path VC2 receives as input the right portion of the first register R3d and the left portion of the third register R6g.

And herein again, simultaneously with the parallel multiplication-accumulation calculations in the two calculation paths VC1, VC2, the hardware calculator CAL is configured to perform, in the first register R3, a loading LD(xₙ₌ₙ₋₂) of the pair of first factors {xₙ₋₅, xₙ₋₆} corresponding to the calculation of the next operation (i.e. the operation after the second operation OP2) of the first path VC1 and of the second path VC2; as well as, in the third register R6, only one other loading LD (bₖ₌ₖ₊₄) of the pair of second factors {b₆, b₇} corresponding to the calculation of the operation following the next operation (i.e. following the operation after the second operation OP2) of the first path VC1.

Consequently, during the next operation (after the second operation OP2), the second register R7 and the third register R6 will contain second factors {b₄, b₅} {b₆, b₇} in a manner comparable to their content at the start of the first operation OP1 and at the start of the second operation OP2.

The implementation of the operation following the second operation OP2 is strictly identical to the first operation OP1, from the point of view of the accesses and the loadings in the input registers R3, R6, R7, but this time loaded with the data corresponding to the respective advancement of the index k in the sum Σₖ₌₀^{N-1}bₖxₘ₋ₖ of rank m=n−1.

It will be noted that, between the first operation OP1 and the second operation OP2, the difference between all actions performed in the second register R7 and the third register R6 corresponds to a switching, that is to say a strict exchange, between the actions performed in the second register R7 and actions performed in the third register R6.

Consequently, in the series of operations, the hardware calculator CAL is configured to switch the functions of the second register R7/R6 and the third register R6/R7, at each successive operation, one after the other. In other words, for each new operation, the third register becomes the second register and the second register becomes the third register, and the same actions are performed in the “new” second register and in the “new” third register.

From another point of view, it can be considered that the hardware calculator CAL always performs strictly the same actions in “one” second register and in “one” third register for each operation. Indeed, in the first operation OP1 (and the “odd” operations), the second register is the register having the reference R7 and the third register is the register having the reference R6; while in the second operation OP2 (and the “even” operations), the exact same actions are executed in a second register and in a third register, the second register being the register having the reference R6 and the third register being the register having the reference R7.

In summary, a technique of hardware calculation of multiplication-accumulation operations has been described, in which, for each operation progressively composing the first output component of lower rank n−1, the first input factors {xᵢ, xᵢ₋₁} are loaded into a first register R3 and the second factors {bⱼ, bⱼ₊₁} are loaded into a second register R7/R6. A third register R6/R7 is further provided to contain the next second factors {bⱼ₊₂, bⱼ₊₃} for the next operation of the first output component of lower rank n−1. At the same time, the multiplication-accumulation operations for the second output component of higher consecutive rank n, between the same first factors {xᵢ, xᵢ₋₁} loaded in the first register R3, and the second factors {bⱼ₊₁, bⱼ₊₂} corresponding to these first factors, distributed in the second register R7/R6 and in the third register R6/R7.

Consequently, the hardware calculation technique thus summarised allows carrying out the four multiplications-accumulations for each operation in the set of the two paths VC1, VC2, with only two loadings in the input registers R3, R7/R6 (REGin—FIG. 1).

It will be noted that an initialisation phase of the series, before the very first operation of the series, comprises three loadings of the input registers R3, R7, R6 with the corresponding data, for example as represented in FIG. 2. Then, throughout the implementation of the series of operations, each operation includes only two loadings.

On the other hand, in the developed expressions of the equations Yₙ₋₁, Yₙ of the formula Yₘ=Σₖ₌₀^{N-1}bₖxₘ₋ₖ illustrated in FIGS. 2, 4 and 6, the indices k of the coefficients bₖ all range from o to N−1, while the indices m−k of the input data xₘ₋ₖ are noted so as to go from the corresponding rank m to the rank m−(N−1). This being the case, it is understood that the index values, such as possibly the value denoted m−(N−1), are considered modulo (N−1) such that when m−k<0 the effective indices are equal to (N−1)+(m−k), given that the input vector {xᵢ}ᵢ typically does not have an index i with a negative sign. In this regard, the values of the input data {xᵢ}ᵢ can typically be stored in a circular register, implementing by construction the modulo function.

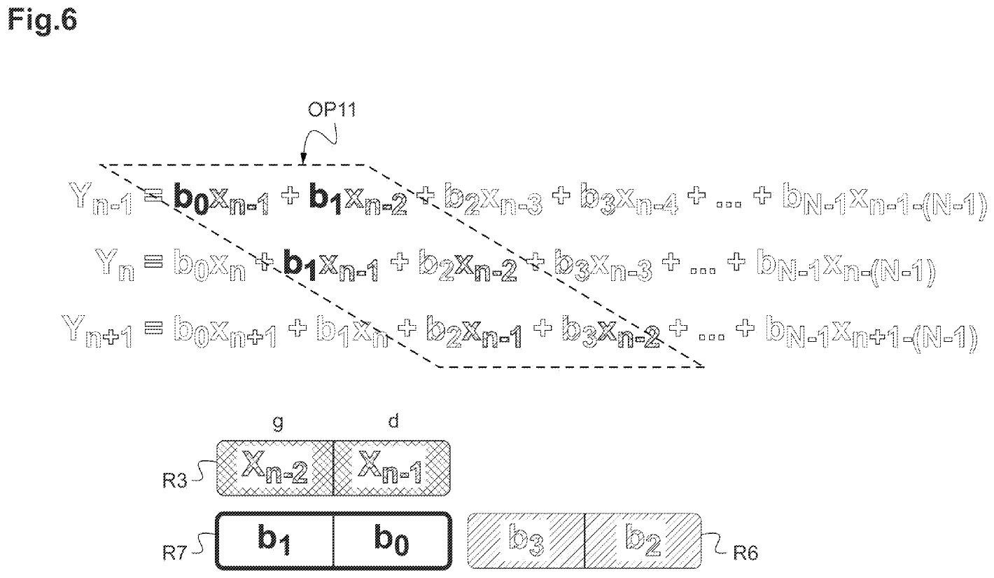

FIG. 6 illustrates a complementary example corresponding to a case where the hardware calculator further includes a third calculation path (not represented), which is similar to the first calculation path VC1 and to the second calculation path VC2, adapted to calculate in parallel a third output component Yₙ₊₁, of a third rank n+1 which is higher than and consecutive to the second rank n, and according to the same formula Yₘ=Σₖ₌₀^{N-1}bₖxₘ₋ₖ.

For each operation, the hardware calculator is configured to calculate and accumulate in a third output register (not represented) a pair of two products {bₖxₘ₋ₖ}_{[k;k+1]}^{m=n+1} between the same first factors {xₙ₋₁, xₙ₋₂} contained in the first register R3 and the second factors {bⱼ₊₂, bⱼ₊₃} contained in the third register R6.

In a first operation OP11, the multiplication-accumulation operations performed for the first output component Yₙ₋₁ by the first path VC1, and for the second output component Yₙ by the second path VC2, correspond precisely to the first operation OP1 which is previously described in relation to FIGS. 2 and 3.

Thus, in the first operation OP1 which is previously described in relation to FIGS. 2 and 3, the third register R6 contains the coefficients {b₂, b₃}.

However, for the terms of the third output component Yₙ₊₁ p by the third path, the second factors of indices k, k+1 corresponding to the products {bₖxₘ₋ₖ}ₖ^{m=n+1} with input data xₙ₋₁, xₙ₋₂ for the rank n+1 (i.e. (n+1)−k=n−1; (n+1)−(k+1)=n−2 i.e. k=2; k+1=3), are the coefficients {b₂, b₃} contained in the third register R6.

The same loadings as those described in relation to FIGS. 2 and 3 are made in the registers R3 and R7 during the first operation OP11.

Then, in a second operation following the first operation OP11, the first register R3 contains the first factors {xₙ₋₃, xₙ₋₄}, the second register R7 contains the second factors {b₄, b₅} and the third register R6 contains the second factors {b₂, b₃}.

Thus, herein again the multiplication-accumulation operations performed for the first output component Yₙ₋₁ by the first path VC1, and for the second output component Yₙ p by the second path VC2, correspond precisely to the second operation OP2 which is previously described in relation to FIGS. 4 and 5.

And, for the terms of the third output component Yₙ₊₁ by the third path, the second factors of indices k, k+1 corresponding to the products {bₖxₘ₋ₖ}ₖ^{m=n+1} with input data xₙ₋₃, xₙ₋₄ for the rank n+1 (i.e. (n+1)−k=n−3; (n+1)−(k+1)=n−4 i.e. k=4; k+1=5), are the coefficients {b₄, b₅} contained in the second register R7.

Consequently, by means of an additional third computation path, the hardware calculator is capable of calculating six multiplication-accumulation terms for two factor loadings into said registers at each operation.

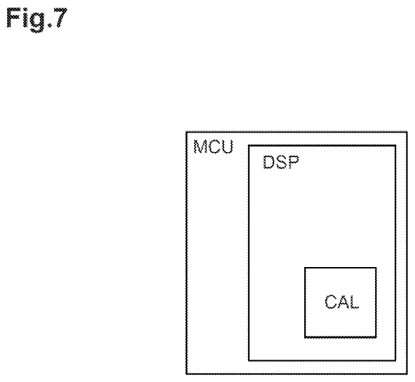

FIG. 7 illustrates an exemplary embodiment of the hardware calculator CAL described previously in relation to FIGS. 2 to 6. The hardware calculator CAL belongs for example to a digital signal processor DSP, produced in an integrated manner within an integrated circuit, such as a microcontroller MCU.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An integrated circuit comprising:
a hardware calculator configured to calculate in parallel a first output component Yₙ₋₁ of a first rank n−1 and a second output component Yₙ of a second rank n which is higher than and consecutive to the first rank, according to the formula: Yₘ=Σₖ₌₀^{N-1}bₖxₘ₋ₖ, in a series of operations,
wherein the hardware calculator includes a first calculation path dedicated to the first output component Yₙ₋₁, a second calculation path dedicated to the second output component Yₙ,
wherein, for each operation, a first register is configured to contain a pair of first factors {xᵢ, xᵢ₋₁} corresponding to terms {bₖxₘ₋ₖ}_{[k;k+1]}^{m=n-1} of an operation in the first path, a second register is configured to contain a pair of second factors {bⱼ, bⱼ₊₁} corresponding to terms {bₖxₘ₋ₖ}_{[k;k+1]}^{m=n-1}of the operation in the first path, and a third register is configured to contain a pair of second factors {bⱼ₊₂, bⱼ₊₃} corresponding to terms {bₖxₘ₋ₖ}_{[k;k+3]}^{m=n-1} of the next operation in the first path, and
wherein the two calculation paths are configured to each access the first register, the second register and the third register, so as to use, in each operation, the first factors xₘ₋ₖ and the second factors bₖ at the corresponding position of the summation index 0≤k≤N−1 in the formula of rank m=n−1, m=n respective to each of the output components Yₙ₋₁, Yₙ.

2. The integrated circuit according to claim 1,
wherein, for each operation, the first calculation path is configured to calculate and accumulate, in a first output register, the pair of two products {bₖxₘ₋ₖ}_{[k;k+1]}^{m=n-1} between the first factors {xᵢ, xᵢ₋₁} contained in the first register and the second factors {bⱼ, bⱼ₊₁} contained in the second register,
wherein, for each operation, the second calculation path is configured to calculate and accumulate, in a second output register, the pair of two products {bₖxₘ₋ₖ}_{[k;k+1]}^{m=n} between the same first factors {xᵢ, xᵢ₋} contained in the first register and the second factors {bⱼ₊₁, bⱼ₊₂} corresponding to the calculation of the second rank n, contained in the second register and in the third register, and
wherein, for each operation, the hardware calculator is configured to load, into the first register, a pair of first factors {xᵢ₋₂, xᵢ₋₃} corresponding to the calculation of the next operation of the first path, and to load, into the second register, a pair of second factors {bⱼ₊₄, bⱼ₊₅} corresponding to the calculation of the operation following the next operation of the first path.

3. The integrated circuit according to claim 1, wherein the hardware calculator is configured, in the series of operations, to switch the functions of the second register and of the third register, for each successive operation.

4. The integrated circuit according to claim 1, wherein the first register, the second register, the third register the first output register and the second output register have a size of 2M bits and each contains a pair of two data items encoded on M bits.

5. The integrated circuit according to claim 1, wherein the hardware calculator includes a selection circuit configured to distribute accesses to the second register and to the third register at the first calculation path and the second calculation path, such that the first path has access to the second factors {bⱼ, bⱼ₊₁} corresponding to the operation contained in the second register, and that the second path has access to the second factors {bⱼ₊₂, bⱼ₊₃} corresponding to the operation contained in the second register and in the third register .

6. The integrated circuit according to claim 1, wherein the hardware calculator is configured to calculate in parallel a third output component Yₙ₊₁, of a third rank n+1 which is higher than and consecutive to the second rank n, according to the same formula, the hardware calculator including a third calculation path dedicated to the third output component Yₙ₊₁, and wherein, for each operation, the hardware calculator is further configured to calculate and accumulate, with the third path, in a third output register a pair of two products {bₖxₘ₋ₖ}_{[k;k+1]}^{m=n+1} between the same first factors {xᵢ, xᵢ₋₁} contained in the first register and the second factors {bⱼ₊₂, bⱼ₊₃} corresponding to the calculation of the third rank n+1, contained in the third register.

7. The integrated circuit according to claim 1, wherein the integrated circuit is a digital signal processor.

8. The integrated circuit comprising:
a hardware calculator configured to calculate in parallel a first output component Yₙ₋₁ of a first rank n−1 and a second output component Yₙ of a second rank n which is higher than and consecutive to the first rank, according to the formula: Yₘ=Σₖ₌₀^{N-1}bₖxₘ₋₋ₖ, in a series of operations,
wherein the hardware calculator includes a first calculation path dedicated to the first output component Yₙ₋₁, a second calculation path dedicated to the second output component Yₙ, a first register configured to contain a pair of first factors {xᵢ, xᵢ₋₁}, a second register configured to contain a pair of second factors {bⱼ, bⱼ₊₁} and a third register configured to contain a pair of second factors {bⱼ₊₂, bⱼ₊₃},
wherein the hardware calculator is, for each operation, configured to:
calculate and accumulate, with the first path, in a first output register, a pair of two products {bₖxₘ₋ₖ}_{[k;k+1]}^{m=n-1} between the first factors {xᵢ, xᵢ₋₁} contained in the first register and the second factors {bⱼ, bⱼ₊₁} contained in the second register;
calculate and accumulate, with the second path, in a second output register, a pair of two products {bₖxₘ₋ₖ}_{[k;k+1]}^{m=n} between the same first factors {xᵢ, xᵢ₋₁} contained in the first register and the second factors {bⱼ₊₁, bⱼ₊₂} corresponding to the calculation of the second rank n, contained in the second register and in the third register;
load, into the first register, a pair of first factors {xᵢ₋₂, xᵢ₋₃} corresponding to the calculation of the next operation of the first path; and
load, into the second register, a pair of second factors {bⱼ₊₄, bⱼ₊₅} corresponding to the calculation of the operation following the next operation of the first path.

9. The integrated circuit according to claim 8, wherein the hardware calculator is configured, in the series of operations, to switch the functions of the second register and of the third register, for each successive operation.

10. The integrated circuit according to claim 8, wherein the first register, the second register, the third register the first output register and the second output register have a size of 2M bits and each contains a pair of two data items encoded on M bits.

11. The integrated circuit according to claim 8, wherein the hardware calculator includes a selection circuit configured to distribute accesses to the second register and to the third register at the first calculation path and the second calculation path, such that the first path has access to the second factors {bⱼ, bⱼ₊₁} corresponding to the operation contained in the second register, and that the second path has access to the second factors {bⱼ₊₂, bⱼ₊₃} corresponding to the operation contained in the second register and in the third register.

12. The integrated circuit according to claim 8, wherein the hardware calculator is configured to calculate in parallel a third output component Yₙ₊₁, of a third rank n+1 which is higher than and consecutive to the second rank n, according to the same formula, the hardware calculator including a third calculation path dedicated to the third output component Yₙ₊₁, and wherein, for each operation, the hardware calculator is further configured to calculate and accumulate, with the third path, in a third output register a pair of two products {bₖxₘ₋ₖ}_{[k;k+1]}^{m=n+1} between the same first factors {xᵢ, xᵢ₋₁} contained in the first register and the second factors {bⱼ₊₂, bⱼ₊₃} corresponding to the calculation of the third rank n+1, contained in the third register.

13. The integrated circuit according to claim 8, wherein the integrated circuit is a digital signal processor.

14. A method of parallel calculation of a first output component Yₙ₋₁ of a first rank n−1 and of a second output component Yₙ of a second rank n, which is higher than and consecutive to the first rank, according to the formula: Yₘ=Σₖ₌₀^{N-1}bₖxₘ₋ₖ, in a series of operations, the method comprising, for each operation:
calculating, by a hardware calculator, the first component Yₙ₋₁ by accumulating two products {bₖxₘ₋ₖ}_{[k;k+1]}^{m=n-1} between first factors {xᵢ, xᵢ₋₁} contained in a first register and second factors {bⱼ, bⱼ₊₁} contained in a second register;
calculating, by the hardware calculator, the second component Yₙ by accumulating two products {bₖxₘ₋ₖ}_{[k;k+1]}^{m=n} between the same first factors {xᵢ, xᵢ₋₁} contained in the first register and the second factors {bⱼ₊₁, bⱼ₊₂} corresponding to a calculation of the second rank n, contained in the second register and in a third register;
loading, by the hardware calculator, into the first register, a pair of first factors {xᵢ₋₂, xᵢ₋₃} corresponding to the calculation of a next operation; and
loading, by the hardware calculator, into the second register, a pair of second factors {bⱼ₊₄, bⱼ₊₅} corresponding to the calculation of the operation following the next operation of the first path.

15. The method according to claim 14, further comprising, in the series of operations, a switching of the functions of the second register and of the third register, for each successive operation.

16. The method according to claim 14, wherein the first register, the second register, the third register, the first output register and the second output register have a size of 2M bits and each contain a pair of two data items encoded on M bits.

17. The method according to claim 14, wherein accesses to the second register and to the third register are distributed such that a first calculation path dedicated to the first output component Yₙ₋₁, has access to the second factors {bⱼ, ⱼ₊₁} corresponding to said operation contained in the second register, and that a second calculation path dedicated to the second output component Yₙ, have access to the second factors {bⱼ₊₂, bⱼ₊₃} corresponding to said operation contained in the second register and in the third register.

18. The method according to claim 14, further comprising a parallel calculation of a third output component Yₙ₊₁, of a third rank n+1, which is higher than and consecutive to the second rank n, according to the same formula, wherein, for each operation, the method further comprises calculating the third component Yₙ₊₁ comprises a calculation and an accumulation of two products {bₖxₘ₋ₖ}_{[k;k+1]}^{m=n+1} between the same first factors {xᵢ, xᵢ₋₁} contained in the first register and the second factors {bⱼ₊₂, bⱼ₊₃} corresponding to the calculation of the third rank n+1, contained in the third register.
